(19) United States
(12) Patent Application Publication
(10) Pub. No.: US 2012/0043605 A1
(43) Pub. Date: Feb. 23, 2012

(54) SEMICONDUCTOR DEVICE AND METHOD FOR FORMING THE SAME

(75) Inventors: Se In KWON, Incheon (KR); Hyun Jin LEE, Seongnam (KR)

(73) Assignee: Hynix Semiconductor Inc., Icheon (KR)

(21) Appl. No.: 13/210,651

(22) Filed: Aug. 16, 2011

(30) Foreign Application Priority Data
Aug. 17, 2010 (KR) 10-2010-0079423

(51) Int. Cl. H01L 29/78

(52) U.S. Cl. 257/331; 257/E29.262

(57) ABSTRACT

A semiconductor device and a method for forming the same are disclosed. The semiconductor device includes a semiconductor substrate including an active region defined by a device isolation film, a trench formed in the device isolation film and the active region, a gate electrode formed at the bottom of the trench, and a high dielectric material layer formed not only over the top of the gate electrode but also over a surface of the trench. As a result, although the gate electrode does not overlap with the junction region, the semiconductor device prevents channel resistance from being increased, resulting in an increase in semiconductor device characteristics.

### CROSS-REFERENCE TO RELATED APPLICATION

The priority of Korean patent application No. 10-2010-0079423 filed on 17 Aug. 2010, the disclosure of which is hereby incorporated in its entirety by reference, is claimed.

### BACKGROUND OF THE INVENTION

Embodiments of the present invention relate to a semiconductor device, and more particularly to a semiconductor device and a method for forming the same.

Recently, most electronic appliances comprise a semiconductor device. Semiconductor devices include electronic elements such as transistors, resistors and capacitors. These electronic elements are designed to perform partial functions of electronic appliances and are integrated on a semiconductor substrate. For example, an electronic appliance, such as a computer or a digital camera, may include a memory chip for storing information and a processing chip for controlling information. The memory chip and the processing chip include electronic elements integrated on a semiconductor substrate.

Semiconductor devices must increase in integration degree in order to satisfy consumer demands for superior performance and low prices. Such an increase in the integration degree of a semiconductor device entails less tolerance in a design rule, thus causing patterns of the semiconductor device to be significantly reduced. Although an entire chip area increases as a semiconductor device becomes miniaturized and more highly integrated, a unit cell area, where patterns of a semiconductor device are actually formed, decreases. Accordingly, since a greater number of patterns should be formed in a limited unit cell area in order to achieve a desired memory capacity, there is a need for formation of microscopic (fine) patterns having a reduced critical dimension (CD: a minimum pattern size available under a given condition).

Nowadays, various methods for forming microscopic patterns have been developed, including, e.g., a method using a phase shift mask as a photo mask, a Contrast Enhancement Layer (CEL) method in which a separate thin film capable of enhancing image contrast is formed on a wafer, a Tri Layer Resist (TLR) method in which an intermediate layer, such as, e.g., a Spin On Glass (SOG) film, is interposed between two photoresist films, or a silylation method for selectively implanting silicon into an upper part of a photoresist film.

Meanwhile, with the increasing integration degree of semiconductor devices, the length of a channel is gradually reduced so that high-density channel doping is necessary to guarantee transistor characteristics and prevent deterioration of refresh characteristics. To accomplish this, there is a newly proposed technology for reducing bit line capacitance in which a recess gate structure is configured as a buried gate structure so that a gate is formed at a lower part of a bit line and both capacitance between the gate and the bit line and total capacitance of the bit line are reduced.

Generally, to form a buried gate, a semiconductor substrate is etched to a predetermined depth so as to form a trench. A gate metal fills the trench, and an etchback process is then performed so that the gate electrode is recessed in the trench. In the etchback process, variation in the etched-back depth may occur. If the gate electrode is under-etched because of an incomplete etchback process, the overlap part between the gate electrode and the junction region is enlarged and Gate Induced Drain Leakage (GIDL) increases, so that characteristics of the semiconductor device are unavoidably deteriorated. On the other hand, if the gate electrode becomes thinner because of an excessive etchback process, the gate electrode may not extend to junction regions, so that channel resistance increases, also resulting in deterioration of the semiconductor device characteristics.

### BRIEF SUMMARY OF THE INVENTION

Various embodiments of the present invention are directed to providing a semiconductor device and a method for forming the same that substantially obviate one or more problems due to limitations and disadvantages of the related art.

An embodiment of the present invention relates to a semiconductor device and a method for forming the same, which can solve problems of the related art, including deterioration of characteristics of the semiconductor device, which may result when excessive etchback or no etchback is performed because of irregular etchback of the buried gate.

In accordance with an aspect of the present invention, a semiconductor device includes a semiconductor substrate including a semiconductor substrate including an active region defined by a device isolation film; first and second trenches formed in the device isolation film and the active region; a first gate electrode formed at a lower part of the first trench; a second gate electrode formed at the bottom a lower part of the second trench; and a high dielectric material layer formed over the first and second the gate electrodes and covering a first sidewall of the first trench and a second sidewall of the second trench, the high dielectric material layer conformally coating the first and second trenches.

The semiconductor device may further include a low dielectric material layer formed over the high dielectric material layer, the high dielectric layer being a continuous layer.

The high dielectric material layer may include HfO₂ or ZrO₂.

The high dielectric material layer may include an oxide film or a nitride film.

The semiconductor device may further include a junction region contained in the active region.

The junction region may not come into direct contact with the gate electrode.

The semiconductor device may further include a hard mask pattern formed over the active region positioned at sides of the gate electrode.

The semiconductor device may further include an insulation film pattern formed over the hard mask pattern and the device isolation film.

In accordance with another aspect of the present invention, a semiconductor device includes first and second buried gate electrodes formed within first and second trenches, respectively, in a substrate; a junction region formed in the substrate and located between the first and second buried gate electrode, the junction region being spaced apart from the first and second buried gate electrode; and a high dielectric layer formed conformally over the first and second trenches and within the first and second trenches, a portion of the high dielectric layer being provided over the junction region.

The high dielectric layer includes material having a dielectric constant of 5 or more.

In accordance with another aspect of the present invention, a method for forming a semiconductor device includes forming a semiconductor substrate including an active region defined by a device isolation film; forming a trench in the device isolation film and the active region; forming a gate electrode at a lower portion of the trench; and forming a high dielectric material over the semiconductor substrate including the gate electrode.

The device isolation film is formed by etching the semiconductor substrate using a hard mask pattern formed over the semiconductor substrate as a mask, and filling an insulation film in a recess formed by etching the semiconductor substrate.

The forming of the trench may include forming an insulation film pattern over the device isolation film and the hard mask pattern; and etching the device isolation film, the hard mask pattern, and the semiconductor substrate in the active region using the insulation film pattern as a mask.

The forming of the gate electrode may include forming a gate electrode layer over the semiconductor substrate including the trench; and performing an etchback process on the gate electrode layer.

The forming of the high dielectric material layer may include forming HfO₂ or ZrO₂.

The method for forming the semiconductor device may further include, after forming the high dielectric material layer, forming a low dielectric material layer.

The forming of the low dielectric material layer may include forming an oxide film or a nitride film.

The method for forming the semiconductor device may further include, after forming the high dielectric material layer, forming a junction region by implanting ions into the active region.

The junction region may not come into direct contact with the gate electrode.

### BRIEF DESCRIPTION OF THE DRAWINGS

FIGS. 1(i) to 1(iii) illustrate a semiconductor device according to an embodiment of the present invention. FIG. 1(i) is a plan view illustrating a semiconductor device, FIG. 1(ii) is a cross-sectional view taken along the line y-y′ of the semiconductor device shown in FIG. 1(i), and FIG. 1(iii) is a cross-sectional view taken along the line x-x′ of the semiconductor device shown in FIG. 1(i).

FIGS. 2A to 2D illustrate a method for forming a semiconductor device according to an embodiment of the present invention. In each of FIGS. 2A to 2D, (i) is a cross-sectional view taken along the line y-y′ of the semiconductor device shown in FIG. 1(i), and (ii) is a cross-sectional view taken along the line x-x′ of the semiconductor device shown in FIG. 1(i).

FIG. 3 is a cross-sectional view illustrating a semiconductor device in which a gate electrode does not overlap with a junction region according to an embodiment of the present invention.

### DESCRIPTION OF EMBODIMENTS

Reference will now be made in detail to embodiments of the present invention, examples of which are illustrated in the accompanying drawings. Wherever possible, the same reference numbers will be used throughout the drawings to refer to the same or like parts.

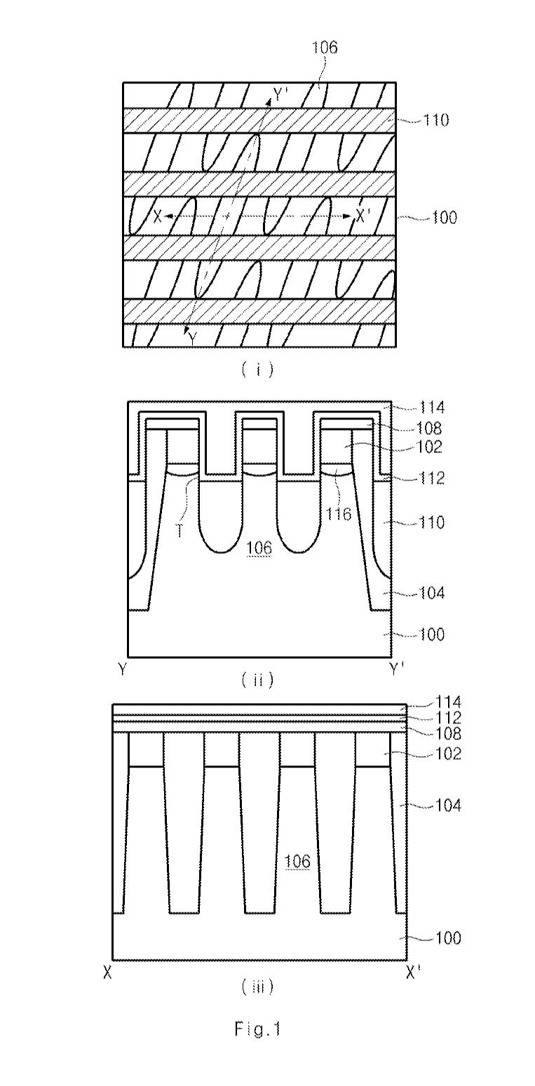

FIGS. 1(i) to 1(iii) illustrate a semiconductor device according to an embodiment of the present invention. FIG. 1(i) is a plan view illustrating a semiconductor device, FIG. 1(ii) is a cross-sectional view taken along the line y-y′ of the semiconductor device shown in FIG. 1(i), and FIG. 1(iii) is a cross-sectional view taken along the line x-x′ of the semiconductor device shown in FIG. 1(i).

Referring to FIGS. 1(i) to 1(iii), the semiconductor device according to an embodiment of the present invention may include a semiconductor substrate 100 including an active region 106 defined by a device isolation film 104, trenches T formed in the device isolation film 104 and the active region 106, a gate electrode 110 formed at the bottom of the trench T, and a high dielectric material layer 112 formed not only over the top of the gate electrode 110 but also over the surface of an insulation film pattern 108.

Preferably, the semiconductor device may further include a low dielectric material layer 114 formed over the high dielectric material layer 112, and a junction region 116 formed in the active region 106. Preferably, the junction region 116 may not overlap with the gate electrode 110. When the junction region 116 is formed to the same depth as the active region 106, refresh characteristics may deteriorate.

The high dielectric material layer 112 may be formed of high-K material having a high dielectric constant, and may include HfO₂ or ZrO₂. In addition, the low dielectric material layer 114 may include a general insulation film having insulation characteristics, for example, an oxide film or a nitride film.

In addition, the above-mentioned semiconductor device may further include a hard mask pattern 102 formed over the junction region 116, and an insulation film pattern 108 formed over the hard mask pattern 102 and the device isolation film 104.

In the case where the gate electrode 110 does not overlap with the junction region 116, the semiconductor device according to an embodiment of the present invention can prevent channel resistance from being increased by the high dielectric material layer 112 formed over the gate electrode 110, and can also prevent a Gate Induced Drain Leakage (GIDL) current from being increased because the gate electrode 110 does not overlap with the junction region 116.

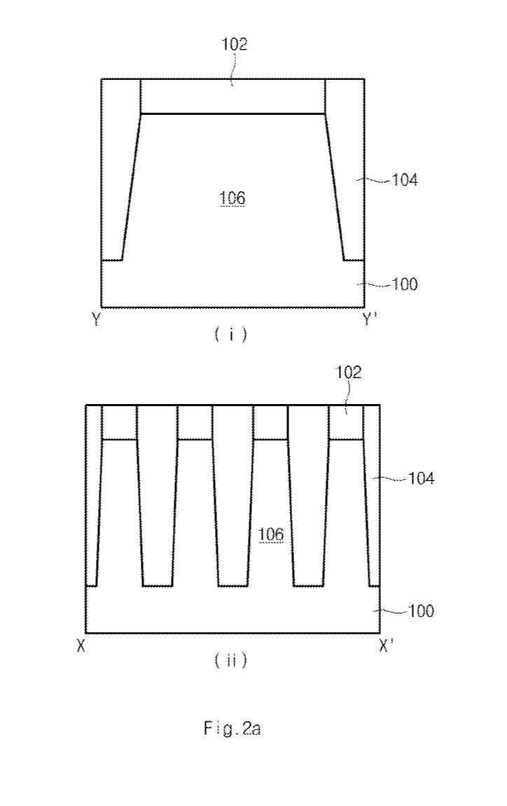

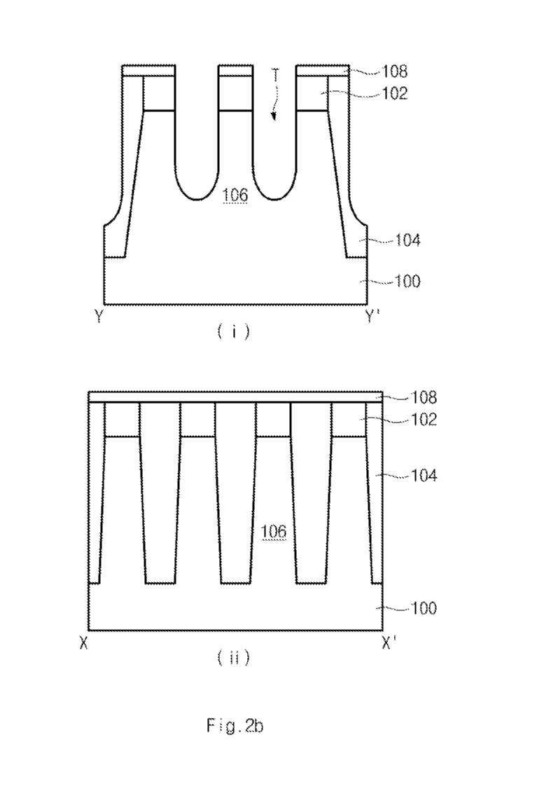

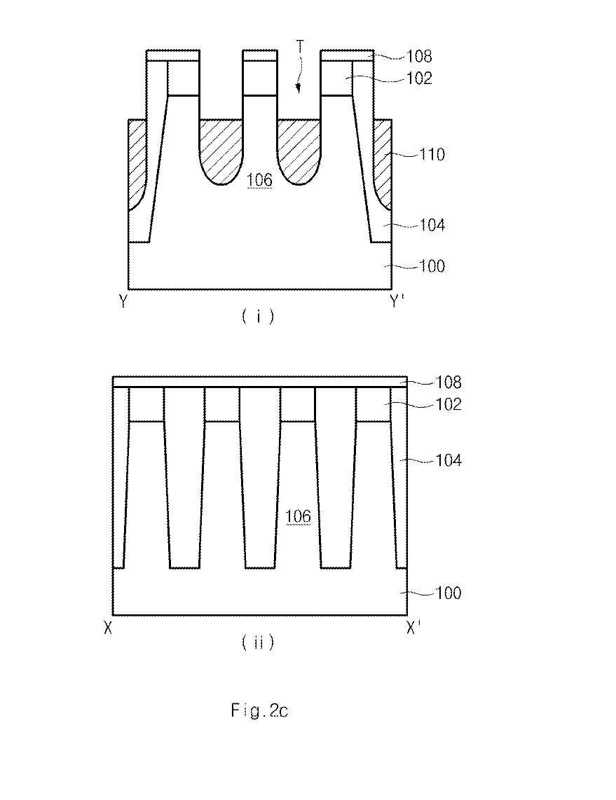

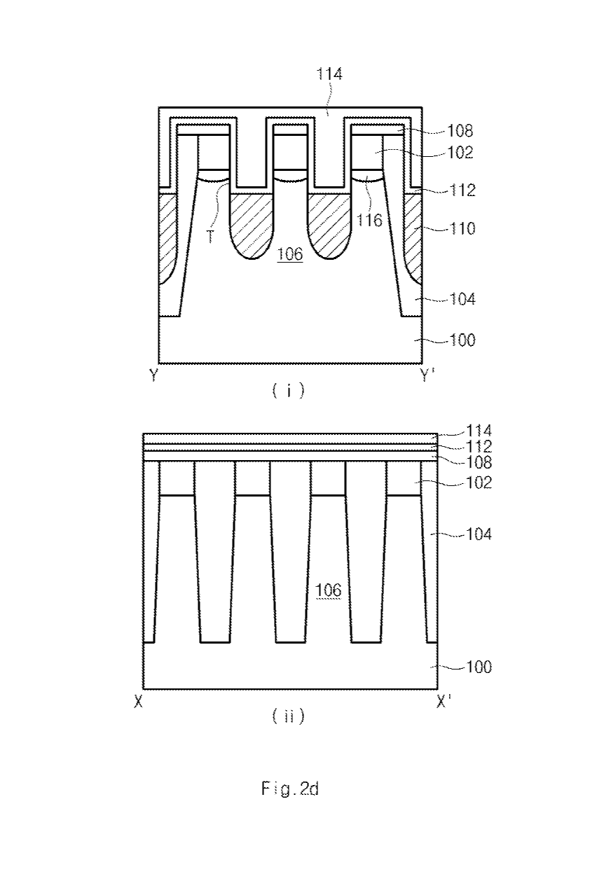

A method for forming the above-mentioned semiconductor device according to an embodiment of the present invention will hereinafter be described with reference to FIGS. 2A to 2D. FIGS. 2A to 2D illustrate a method for forming a semiconductor device according to an embodiment of the present invention. In each of FIGS. 2A to 2D, (i) is a cross-sectional view taken along the line y-y′ of the semiconductor device shown in FIG. 1(i), and (ii) is a cross-sectional view taken along the line x-x′ of the semiconductor device shown in FIG. 1(i).

Referring to FIG. 2A, a hard mask pattern 102 is formed over a semiconductor substrate 100. The semiconductor substrate 100 is etched using the hard mask pattern 102 as a mask, and an insulation film is buried. A planarization etch process is performed on the insulation film in such a manner that the hard mask pattern 102 is exposed, thereby forming a device isolation film 104. The active region 106 is defined by the device isolation film 104.

Referring to FIG. 2B, an insulation film pattern 108 is formed over the device isolation film 104 and the hard mask pattern 102, and the device isolation film 104 and the active region 106 are etched using the insulation film pattern 108 as a mask, so that the trench T may be formed.

Referring to FIG. 2C, a gate electrode material is formed in the trench T so that the trench T is filled with the gate electrode material, and the gate electrode material is etched back to form a gate electrode 110. Although not shown in FIG. 2C, an oxide film may be formed over the trench, and the gate electrode 110 may include a barrier metal and a conductive layer. Preferably, the barrier metal may include TiN material, and the conductive layer may include tungsten (W).

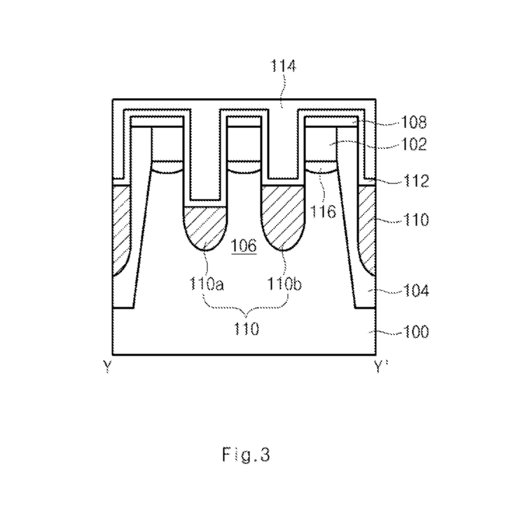

Referring to FIG. 2D, a high dielectric material layer (i.e., a high-K layer having a high dielectric constant) 112 may be formed over the gate electrode 110 and the insulation film pattern 108. In this case, the high dielectric material layer (i.e., the high-K layer) 112 may include HfO₂ or ZrO₂. The high dielectric material layer 112 may be used as a cap between the gate electrode 110 and a junction region 116 formed in a subsequent process, and may be used as a junction because it can attract many electrons. The role of the high dielectric material layer 112 will hereinafter be described with reference to FIG. 3. A low dielectric material layer 114 is formed over the high dielectric material layer 112. Preferably, the low dielectric material layer 114 may include a general insulation film having insulation characteristics. For example, the low dielectric material layer 114 may include an oxide film or a nitride film. Subsequently, ions are implanted in the active region 106 so that the junction region 116 is formed. Preferably, the junction region 116 may be formed to a depth so as not to overlap with the gate electrode 110.

FIG. 3 is a cross-sectional view illustrating a semiconductor device in which a gate electrode does not overlap with a junction region according to an embodiment of the present invention. In FIG. 3, the gate electrode 110 does not come into contact with the junction region 116. In more detail, as can be seen from FIG. 3, the junction region 116 is formed at a higher level than the gate electrode 110. Although the gate electrode 110 does not come into direct contact with the junction region 116, an embodiment of the present invention can further prevent channel resistance from being increased by the high dielectric material layer 112 formed between the gate electrode 110 and the junction region 116. In addition, since the gate electrode 110 and the junction region 116 are not in contact and are spaced apart from each other, GIDL can be prevented.

Forming the gate electrode 110 so that it is not indirect contact with the junction region 116 may be achieved by performing a deep etch back onto the gate electrode 110 and performing a shallow junction implant. Such deep etch back can prevent the occurrence of non-etched gate electrode, and can reduce the etchback variation of the gate electrode. In addition, in a semiconductor device according to the present invention, since the gate electrode 110 is not in direct contact with the junction region 116, channel resistance can be reduced, resulting in increased refresh characteristics.

As is apparent from the above description, according to the embodiments of the present invention, during the etchback process of the gate electrode to form a buried gate, although the gate electrode does not come in direct contact with the junction region, for example, because of etchback variation, an increase in channel resistance is prevented by employing a high dielectric material layer between the gate electrode and the junction region, which also results in a reduction in a GIDL current.

The above embodiments of the present invention are illustrative and not limitative. Various alternatives and equivalents are possible. The invention is not limited by the type of deposition, etching, polishing, and patterning steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

An embodiment of the present invention includes the following methods:

1. A method for forming a semiconductor device comprising:

forming a semiconductor substrate including an active region defined by a device isolation film;

forming a trench in the device isolation film and the active region;

forming a gate electrode at a lower portion of the trench; and

forming a high dielectric material over the semiconductor substrate including the gate electrode.

2. The method according to claim 1, wherein the device isolation film is formed by etching the semiconductor substrate using a hard mask pattern formed over the semiconductor substrate as a mask, and filling an insulation film in a recess formed by etching the semiconductor substrate.

3. The method according to claim 2, wherein the forming of the trench includes:

forming an insulation film pattern over the device isolation film and the hard mask pattern; and

etching the device isolation film, the hard mask pattern, and the semiconductor substrate in the active region using the insulation film pattern as a mask.

4. The method according to claim 1, wherein the forming of the gate electrode includes:

forming a gate electrode layer over the semiconductor substrate including the trench; and performing an etchback process on the gate electrode layer.

5. The semiconductor device according to claim 1, wherein the high dielectric material layer includes HfO₂ or ZrO₂.

6. The method according to claim 1, the method further comprising:

forming a low dielectric material layer over the high dielectric material layer.

7. The method according to claim 6, wherein the low dielectric material layer includes an oxide film or a nitride film.

8. The method according to claim 1, the method further comprising:

forming a junction region by implanting ions into the active region located at sides of the gate electrode.

9. The method according to claim 8, wherein the junction region does not come into direct contact with the gate electrode.

What is claimed is:

1. A semiconductor device comprising:
a semiconductor substrate including an active region defined by a device isolation film;
first and second trenches formed in the device isolation film and the active region;
a first gate electrode formed at a lower part of the first trench;
a second gate electrode formed at the bottom a lower part of the second trench; and
a high dielectric material layer formed over the first and second the gate electrodes and covering a first sidewall of the first trench and a second sidewall of the second trench, the high dielectric material layer conformally coating the first and second trenches.

2. The semiconductor device according to claim 1, the device further comprising a low dielectric material layer formed over the high dielectric material layer, the high dielectric layer being a continuous layer.

3. The semiconductor device according to claim 1, wherein the high dielectric material layer includes HfO₂ or ZrO₂.

4. The semiconductor device according to claim 2, wherein the high dielectric material layer includes an oxide film or a nitride film.

5. The semiconductor device according to claim 1, the device further comprising a junction region contained in the active region.

6. The semiconductor device according to claim 5, wherein the junction region does not come into direct contact with the first gate electrode.

7. The semiconductor device according to claim 1, the device further comprising a hard mask pattern formed over the active region positioned at sides of the gate electrode.

8. The semiconductor device according to claim 7, the device further comprising an insulation film pattern formed over the hard mask pattern and the device isolation film.

9. A semiconductor device comprising:
first and second buried gate electrodes formed within first and second trenches, respectively, in a substrate;
a junction region formed in the substrate and located between the first and second buried gate electrode, the junction region being spaced apart from the first and second buried gate electrode; and
a high dielectric layer formed conformally over the first and second trenches and within the first and second trenches, a portion of the high dielectric layer being provided over the junction region.

10. The semiconductor device of claim 9, wherein the high dielectric layer includes material having a dielectric constant of 5 or more.
